(19) United States
(12) Patent Application Publication
(10) Pub. No.: US 2008/0311483 A1
(43) Pub. Date: Dec. 18, 2008

(54) Radiation-Crosslinking And Thermally Crosslinking PU Systems-Based On Poly(epsilon-Caprolactone) Polyester Polyols

(75) Inventors: Nicolas Stockel, Koln (DE); Friedrich-Karl Bruder, Krefeld (DE); Meike Niesten, Koln (DE); Harald Blum, Leverkusen (DE); Stephanie Strazisar, Venetia, PA (US)

Correspondence Address: Connolly Bove Lodge & Hutz LLP, P.O. Box 2207, 1007 North Orange Street, Wilmington, DE, 19899-2207, US

(73) Assignee: Bayer MaterialScience AG, Leverkusen (DE)

(21) Appl. No.: 12/100,783

(22) Filed: Apr. 10, 2008

Related U.S. Application Data
(60) Provisional application No. 60/922,981, filed on Apr. 11, 2007.

(51) Int. Cl. G03F 7/00; C08F 2/46; C08L 75/06

(52) U.S. Cl. 430/2; 522/96; 525/131; 524/590

(57) ABSTRACT

The present invention provides polyurethane systems which cure by radiation and thermal action with crosslinking, and use thereof for the production of holographic media. The polyurethane compositions of the invention comprise A) polyisocyanates, B) polyols, comprising at least one poly(ε-caprolactone)polyester polyol, C) compounds having groups which react on exposure to actinic radiation with ethylenically unsaturated compounds with polymerization (radiation-curing groups), D) optionally free radical stabilizers and E) photoinitiators.

### CROSS-REFERENCE TO RELATED APPLICATION

This application claims priority under 35 U.S.C. § 119(e) to provisional application Ser. No. 60/922,981, filed Apr. 11, 2007 which is incorporated by reference in its entirety for all useful purposes.

### FIELD OF THE INVENTION

The present invention relates to polyurethane systems which cure by radiation and thermal action with crosslinking, and the use thereof for the production of holographic media.

### BACKGROUND OF THE INVENTION

In the production of holographic media, as described in U.S. Pat. No. 6,743,552, information is stored in a polymer layer which substantially consists of a matrix polymer and very special polymerizable monomers distributed uniformly therein. This matrix polymer may be based on polyurethane. It is prepared as a rule starting from NCO-functional prepolymers which are crosslinked with polyols, such as polyethers or polyesters, with urethane formation.

However, what is problematic is that optical impairment, such as opacity phenomena of the storage layer, frequently occurs owing to the incompatibilities between such urethane matrices and radiation-curing monomers.

Systems comprising polyisocyanates, polyols and radiation-curing compounds, such as photochemically crosslinking reactive diluents, are known in individual cases from the area of coating technology (U.S. Pat. No. 4,247,578, DE 197 09 560). Polyol components mentioned are substantially polyether- or polyester-based ones or polyacrylatepolyols. Nothing specific is stated regarding their compatibilities with the olefinically unsaturated compounds likewise present, such as acrylate-based reactive diluents.

### SUMMARY OF THE INVENTION

It was an object of the present invention to provide polyurethane systems which are suitable for the production of storage layers for holographic storage media and which have optically satisfactory compatibility of polyurethane matrix polymer with the olefinically unsaturated radiation-curing monomers present therein.

It has now been found that excellent compatibility of matrix polymer with the unsaturated monomers is obtained precisely when poly(ε-caprolactone)polyester polyols are used as a building block for the matrix polymers.

The invention relates to polyurethane systems comprising
A) polyisocyanates,
B) polyols, comprising at least one poly(ε-caprolactone)polyester polyol,
C) compounds having groups which react on exposure to actinic radiation with ethylenically unsaturated compounds with polymerization (radiation-curing groups),
D) optionally free radical stabilizers and
E) photoinitiators.

### DETAILED DESCRIPTION OF THE INVENTION

As used herein in the specification and claims, including as used in the examples and unless otherwise expressly specified, all numbers may be read as if prefaced by the word “about”, even if the term does not expressly appear. Also, any numerical range recited herein is intended to include all sub-ranges subsumed therein.

Polyisocyanates of component A) which may be used are all compounds well known per se to the person skilled in the art or mixtures thereof, which on average have two or more NCO functions per molecule. These may have an aromatic, araliphatic, aliphatic or cycloaliphatic basis. Monoisocyanates and/or polyisocyanates containing unsaturated groups may also be concomitantly used in minor amounts.

For example, butylene diisocyanate, hexamethylene diisocyanate (HDI), isophorone diisocyanate (IPDI), 1,8-diisocyanato-4-(isocyanatomethyl)octane, 2,2,4- and/or 2,4,4-trimethylhexamethylene diisocyanate, the isomeric bis(4,4′-isocyanatocyclohexyl)methanes and mixtures thereof having any desired isomer content, isocyanatomethyl-1,8-octane diisocyanate, 1,4-cyclohexylene di-isocyanate, the isomeric cyclohexanedimethylene diisocyanates, 1,4-phenylene-diisocyanate, 2,4- and/or 2,6-toluene diisocyanate, 1,5-naphthylene diisocyanate, 2,4′- or 4,4′-diphenylmethane diisocyanate and/or triphenylmethane 4,4′,4″-triisocyanate are suitable.

The use of derivatives of monomeric di- or triisocyanates having urethane, urea, carbodiimides, acylurea, isocyanurate, allophanate, biuret, oxadiazinetrione, uretdione and/or iminooxadiazinedione structures is also possible.

The use of polyisocyanates based on aliphatic and/or cycloaliphatic di- or triisocyanates is preferred.

The polyisocyanates of component A) are particularly preferably dimerized or oligomerized aliphatic and/or cycloaliphatic di- or triisocyanates.

Isocyanurates, uretdiones and/or iminooxadiazinediones based on HDI, 1,8-diisocyanato-4-(isocyanatomethyl)octane or mixtures thereof are very particularly preferred.

The component A) preferably has at least 60% by weight of polyisocyanates based on aliphatic and/or cycloaliphatic di- and/or triisocyanates.

The NCO groups of the polyisocyanates of component A) may also be completely or partly blocked with the blocking agents customary per se in industry. These are, for example, alcohols, lactams, oximes, malonic esters, alkyl acetoacetates, triazoles, phenols, imidazoles, pyrazoles and amines, such as, for example, butanone oxime, diisopropylamine, 1,2,4-triazole, dimethyl-1,2,4-triazole, imidazole, diethyl malonate, ethyl acetoacetate, acetone oxime, 3,5-dimethylpyrazole, epsilon-caprolactam, N-tert-butylbenzylamine, cyclopentanone carboxyethyl ester or any desired mixtures of these blocking agents.

The poly(ε-caprolactone)polyester polyols of component B) preferably have number average molar masses of from 500 to 2000 g/mol. They furthermore preferably have an average OH functionality of from 1.5 to 4, particularly preferably from 1.5 to 3.5, very particularly preferably from 2 to 3. They furthermore preferably have a melting point in the range from 10 to 35° C.

In addition to the poly(ε-caprolactone)polyester polyols used in the present invention, further polyfunctional, isocyanate-reactive compounds, such as polyester, polyether, polycarbonate, poly(meth)acrylate and/or polyurethane polyols, can also be used.

Linear polyester diols or branched polyester polyols, as obtained in known manner from aliphatic, cycloaliphatic or aromatic di- or polycarboxylic acids or their anhydrides with polyhydric alcohols having an OH functionality of >2 are suitable as polyester polyols for example.

Examples of such di- or polycarboxylic acids or anhydrides are succinic, glutaric, adipic, pimelic, suberic, azelaic, sebacic, nonanedicarboxylic, decanedicarboxylic, terephthalic, isophthalic, o-phthalic, tetrahydrophthalic, hexahydrophthalic or trimellitic acid and acid anhydrides, such as o-phthalic, trimellitic or succinic anhydride, or any desired mixtures thereof with one another.

Examples of such suitable alcohols are ethanediol, di-, tri- or tetraethylene glycol, 1,2-propanediol, di-, tri- or tetrapropylene glycol, 1,3-propanediol, 1,4-butanediol, 1,3-butanediol, 2,3-butanediol, 1,5-pentanediol, 1,6-hexanediol, 2,2-dimethyl-1,3-propanediol, 1,4-dihydroxycyclohexane, 1,4-dimethylolcyclohexane, 1,8-octanediol, 1,10-decanediol, 11,12-dodecandiol, trimethylolpropane, glycerol or any desired mixtures thereof with one another.

The polyester polyols may also be based on natural raw materials, such as caster oil. It is also possible for the polyester polyols to be based on homo- or copolymers of lactones, as can preferably be obtained by an addition reaction of lactones or lactone mixtures, such as butyrolactone, ε-caprolactone and/or methyl-ε-caprolactone, with hydroxyl-functional compounds, such as polyhydric alcohols having an OH functionality of ≧2, for example of the abovementioned type.

Such polyester polyols preferably have number average molar masses of from 400 to 4000 g/mol, particularly preferably from 500 to 2000 g/mol. Their OH functionality is preferably from 1.5 to 3.5, particularly preferably from 1.8 to 3.0.

Suitable polycarbonate polyols can be accessed in a manner known per se by reacting organic carbonates or phosgene with diols or diol mixtures.

Suitable organic carbonates are dimethyl, diethyl and diphenyl carbonate.

Suitable diols or diol mixtures comprise the polyhydric alcohols mentioned per se in relation to the polyester segments and having an OH functionality of ≧2, preferably 1,4-butanediol, 1,6-hexanediol and/or 3-methylpentanediol.

Such polycarbonate polyols preferably have number average molar masses of from 400 to 4000 g/mol, particularly preferably from 500 to 2000 g/mol. The OH functionality of these polyols is preferably from 1.8 to 3.2, particularly preferably from 1.9 to 3.0.

Suitable polyether polyols are polyadducts of cyclic ethers with OH- or NH-functional initiator molecules, which polyadducts optionally have a block structure.

Suitable cyclic ethers are, for example, styrene oxides, ethylene oxide, propylene oxide, tetrahydrofuran, butylene oxide, epichlorohydrin and any desired mixtures thereof.

Initiators which may be used are the polyhydric alcohols mentioned per se in relation to the polyester polyols and having an OH functionality of ≧2 and primary or secondary amines and aminoalcohols.

Such polyether polyols preferably have number average molar masses of from 250 to 10 000 g/mol, particularly preferably from 500 to 4000 g/mol and very particularly preferably from 600 to 2000 g/mol. The OH functionality is preferably from 1.5 to 4.0, particularly preferably from 1.8 to 3.0.

In addition, aliphatic, araliphatic or cycloaliphatic di-, tri- or polyfunctional alcohols which have a low molecular weight, i.e. molecular weights of less than 500 g/mol, and are short-chain, i.e. contain 2 to 20 carbon atoms, are also suitable as polyfunctional, isocyanate-reactive compounds as constituents of component B).

These may be, for example, ethylene glycol, diethylene glycol, triethylene glycol, tetraethylene glycol, dipropylene glycol, tripropylene glycol, 1,2-propanediol, 1,3-propanediol, 1,4-butanediol, neopentylglycol, 2-ethyl-2-butylpropanediol, trimethylpentanediol, diethyloctanediol positional isomers, 1,3-butylene glycol, cyclohexanediol, 1,4-cyclohexanedimethanol, 1,6-hexanediol, 1,2- and 1,4-cyclohexanediol, hydrogenated bisphenol A (2,2-bis(4-hydroxycyclohexyl)propane), 2,2-dimethyl-3-hydroxypropyl 2,2-dimethyl-3-hydroxypropionate. Examples of suitable triols are trimethylolethane, trimethylolpropane or glycerol. Suitable alcohols having a higher functionality are ditrimethylolpropane, pentaerythritol, dipentaerythritol or sorbitol.

Also suitable are amino alcohols, such as, for example, ethanolamine, diethanolamine, 2-(N,N-dimethylamino)ethylamine, N-methyldiethanolamine, N-methyldiisopropanolamine, N-ethyldiethanolamine, N-ethyldiisopropanolamine, N-N′-bis(2-hydroxyethyl)perhydropyrazine, N-methylbis(3-aminopropyl)amine, N-methylbis(2-aminoethyl)amine, N,N′,N″-trimethyl-diethylenetriamine, N,N-dimethylaminoethanol, N,N-diethylaminoethanol, 1-N,N-diethyl-amino-2-aminoethane, 1-N,N-diethylamino-3-aminopropane, 2-dimethylaminomethyl-2-methyl-1,3-propanediol, N-isopropyldiethanolamine, N-butyldiethanolamine, N-isobutyldiethanolamine, N-oleyldiethanolamine, N-stearyldiethanolamine, oxethylated cocoa fatty amine, N-allyldiethanolamine, N-methyldiisopropanolamine, N,N-propyldiisopropanolamine, N-butyldiisopropanolamine and/or N-cyclohexyldiisopropanolamine.

If concomitantly used, poly(propylene oxides), polyethylene oxide-propylene oxides and/or poly(tetrahydrofurans) having an OH functionality of from 2 to 4 and a number average molar mass of from 250 to 5000 g/mol, preferably having a number average molar mass of from 400 to 3000 g/mol and particularly preferably having a number average molar mass of from 500 to 2000 g/mol are suitable as further polyols in addition to the poly(ε-caprolactone)polyester polyols essential to the invention. Polycarbonate polyol can also be concomitantly used in proportion.

The proportion of the poly(ε-caprolactone)polyester polyols used in the present invention, based on component B), is at least 20% by weight, preferably at least 40% by weight.

In component C), α,β-unsaturated carboxylic acid derivatives, such as acrylates, methacrylates, maleates, fumarates, maleimides, acrylamides and furthermore vinyl ethers, propylene ether, allyl ether and compounds containing dicyclopentadienyl units and olefinically unsaturated compounds, such as styrene, α-methylstyrene, vinyltoluene, vinylcarbazole, olefins, such as, for example, 1-octene and/or 1-decene, vinyl esters, such as, for example, ®VeoVa 9 and/or ®VeoVa 10 from Shell, (meth)acrylonitrile, (meth)acrylamide, methacrylic acid, acrylic acid and any desired mixtures thereof may be used. Acrylates and methacrylates are preferred, and acrylates are particularly preferred.

Esters of acrylic acid or methacrylic acid are generally referred to as acrylates or methacrylates. Examples of acrylates and methacrylates which may be used are methyl acrylate, methyl methacrylate, ethyl acrylate, ethyl methacrylate, ethoxyethyl acrylate, ethoxyethyl methacrylate, n-butyl acrylate, n-butyl methacrylate, tert-butyl acrylate, tert-butyl methacrylate, hexyl acrylate, hexyl methacrylate, 2-ethylhexyl acrylate, 2-ethylhexyl methacrylate, butoxyethyl acrylate, butoxyethyl methacrylate, lauryl acrylate, lauryl methacrylate, isobornyl acrylate, isobornyl methacrylate, phenyl acrylate, phenyl methacrylate, p-chlorophenyl acrylate, p-chlorophenyl methacrylate, p-bromophenyl acrylate, p-bromophenyl methacrylate, trichlorophenyl acrylate, trichlorophenyl methacrylate, tribromophenyl acrylate, tribromophenyl methacrylate, pentachlorophenyl acrylate, pentachlorophenyl methacrylate, pentabromophenyl acrylate, pentabromophenyl methacrylate, pentabromobenzyl acrylate, pentabromobenzyl methacrylate, phenoxyethyl acrylate, phenoxyethyl methacrylate, phenoxyethoxyethyl acrylate, phenoxyethoxyethyl methacrylate, 2-naphthyl acrylate, 2-naphthyl methacrylate, 1,4-bis-(2-thionaphthyl)-2-butyl acrylate, 1,4-bis-(2-thionaphthyl)-2-butyl methacrylate, bisphenol A diacrylate, bisphenol A dimethacrylate, tetrabromobisphenol A diacrylate, tetrabromobisphenol A dimethacrylate, 2,2,2-trifluoroethyl acrylate, 2,2,2-trifluoroethyl methacrylate, 1,1,1,3,3,3-hexafluoroisopropyl acrylate, 1,1,1,3,3,3-hexafluoroisopropyl methacrylate, 2,2,3,3,3-pentafluoropropyl acrylate and/or 2,2,3,3,3-pentafluoropropyl methacrylate.

Epoxy acrylates also suitable as component C) can be obtained as reaction products of bisphenol A diglycidyl ether with hydroxyalkyl (meth)acrylates and carboxylic acids, the bisphenol A diglycidyl ether first being reacted with hydroxyalkyl (meth)acrylate with catalysis by Lewis acid and this hydroxyl-functional reaction product then being esterified with a carboxylic acid by a method known to the person skilled in the art. Bisphenol A diglycidyl ether itself and brominated variants, such as, for example, tetrabromobisphenol A diglycidyl ether (from Dow Chemical, D.E.R. 542), can advantageously be used as the diepoxide. All hydroxyl-functional acrylates described above can be used as hydroxyalkyl (meth)acrylates, in particular 2-hydroxyethyl acrylate, hydroxypropyl acrylate, 4-hydroxybutyl acrylate, poly(ε-caprolactone) mono (meth)acrylates and poly(ethylene glycol) mono(meth)acrylates. All monofunctional carboxylic acids are in principle suitable as the carboxylic acid, in particular those having aromatic substituents. Propane-2,2-diylbis[(2,6-dibromo-4,1-phenylene)oxy(2-{[3,3,3-tris(4-chloro-phenyl)propanoyl]oxy}propane-3,1-diyl)oxyethane-2,1-diyl] diacrylate has proved to be a preferred compound of this class of epoxy acrylates.

Vinylaromatics suitable for component C) are styrene, halogenated derivatives of styrene, such as, for example, 2-chlorostyrene, 3-chlorostyrene, 4-chlorostyrene, 2-bromostyrene, 3-bromostyrene, 4-bromostyrene, p-(chloromethyl)styrene, p-(bromomethyl)styrene or 1-vinylnaphthalene, 2-vinylnaphthalene, 2-vinylanthracene, N-vinylpyrrolidone, 9-vinylanthracene, 9-vinylcarbazole or difunctional compounds, such as divinylbenzene. Vinyl ethers, such as, for example, butyl vinyl ether, are also suitable.

Preferred compounds of component C) are 9-vinylcarbazole, vinylnaphthalene, bisphenol A diacrylate, tetrabromobisphenol A diacrylate, 1,4-bis-(2-thionaphthyl)-2-butyl acrylate, pentabromophenyl acrylate, naphthyl acrylate and propane-2,2-diylbis[(2,6-dibromo-4,1-phenylene)oxy(2-{[3,3,3-tris(4-chlorophenyl)propanoyl]-oxy}propane-3,1-diyl)oxyethane-2,1-diyl] diacrylate.

One or more free radical stabilizers are used as component D). Inhibitors and antioxidants, as described in “Methoden der organischen Chemie [Methods of Organic Chemistry]” (Houben-Weyl), 4th edition, volume XIV/1, page 433 et seq., Georg Thieme Verlag, Stuttgart 1961, are suitable. Suitable classes of substances are, for example, phenols, such as for example, 2,6-di-tert-butyl-4-methylphenol, cresols, hydroquinones, benzyl alcohols, such as benzhydrol, optionally also quinones, such as, for example, 2,5-di-tert-butylquinone, optionally also aromatic amines, such as diisopropylamine or phenothiazine. Preferred free radical stabilizers are 2,6-di-tert-butyl-4-methylphenol, phenothiazine and benzhydrol.

One or more photoinitiators are used as component E). These are usually initiators which can be activated by actinic radiation and initiate a free radical polymerization of the corresponding polymerizable groups. Photoinitiators are commercially sold compounds known per se, a distinction being made between monomolecular (type I) and bimolecular (type II) initiators. (Type I) systems are, for example, aromatic ketone compounds, e.g. benzophenones, in combination with tertiary amines, alkylbenzophenones, 4,4′-bis(dimethylamino)benzophenone (Michler's ketone), anthrone and halogenated benzophenones or mixtures of said types. (Type II) initiators, such as benzoin and its derivatives, benzyl ketals, acylphosphine oxides, e.g. 2,4,6-trimethyl-benzoyldiphenylphosphine oxide, bisacylophosphine oxides, phenylglyoxylic acid esters, camphorquinone, α-aminoalkylphenones, α,α-dialkoxyacetophenones, 1-[4-(phenyl-thio)phenyl]octane-1,2-dione-2-(O-benzoyloxime) and α-hydroxyalkylphenones, are furthermore suitable. The photoinitiator systems described in EP-A 0223587 and consisting of a mixture of an ammonium arylborate and one or more dyes can also be used as a photoinitiator. For example, tetrabutylammonium triphenylhexylborate, tetrabutylammonium tris-(3-fluorophenyl)hexylborate and tetramethylammonium tris-(3-chloro-4-methylphenyl)hexylborate are suitable as the ammonium arylborate. Suitable dyes are, for example, new methylene blue, thionine, Basic Yellow, pinacyanol chloride, rhodamine 6G, gallocyanine, ethyl violet, Victoria Blue R, Celestine Blue, quinaldine red, crystal violet, brilliant green, Astrazon Orange G, Darrow Red, pyronine Y, Basic Red 29, pyrillium I, cyanine, methylene blue and azure A.

It may also be advantageous to use mixture of these compounds. Depending on the radiation source used for curing, type and concentration must be adapted to photoinitiator in a manner known to the person skilled in the art. Further details are described, for example, in P. K. T. Oldring (Ed.), Chemistry & Technology of UV & EB Formulations For Coatings, Inks & Paints, vol 3, 1991, SITA Technology, London, pages 61-328.

Preferred photoinitiators are 2,4,6-trimethylbenzoyldiphenylphosphine oxide, 1-[4-(phenyl-thio)phenyl]octane-1,2-dione-2-(O-benzoyloxime) and mixtures of tetrabutylammonium tris(3-fluorophenyl)hexylborate, tetramethylammonium tris(3-chloro-4-methylphenyl)hexylborate with dyes, such as, for example, methylene blue, new methylene blue, azure A, pyrillium I, cyanine, gallocyanine, brilliant green, crystal violet and thionine.

Furthermore, one or more catalysts may be used in the PU systems according to the invention. These preferably catalyze the urethane formation. Amines and metal compounds of the metals tin, zinc, iron, bismuth, molybdenum, cobalt, calcium, magnesium and zirconium are preferably suitable for this purpose. Tin octanoate, zinc octanoate, dibutyltin dilaurate, dimethyltin dicarboxylate, iron(III) acetylacetonate, iron(II) chloride, zinc chloride, tetraalkylammonium hydroxides, alkali metal hydroxides, alkali metal alcoholates, alkali metal salts of long-chain fatty acids having 10 to 20 carbon atoms and optionally OH side groups, lead octanoate or tertiary amines, such as triethylamine, tributylamine, dimethylbenzylamine, dicyclohexylmethylamine, dimethylcyclohexylamine, N,N,N′,N′-tetramethyldiaminodiethylether, bis(dimethylamino-propyl)urea, N-methyl- or N-ethylmorpholine, N,N′-dimorpholinodiethyl ether (DMDEE), N-cyclohexylmorpholine, N,N,N′,N′-tetramethylethylenediamine, N,N,N′,N′-tetramethyl-butanediamine, N,N,N′,N′-tetramethyl-1,6-hexanediamine, pentamethyldiethylenetriamine, dimethylpiperazine, N-dimethylaminoethylpiperidine, 1,2-dimethylimidazole, N-hydroxy-propylimidazole, 1-azabicyclo[2.2.0]octane, 1,4-diazabicyclo[2.2.2]octane (Dabco), or alkanolamine compounds such as triethanolamine, triisopropanolamine, N-methyl- and N-ethyl-diethanolamine, dimethylaminoethanol, 2-(N,N-dimethylaminoethoxy)ethanol, or N-tris(dialkyl-aminoalkyl)hexahydrotriazines, e.g. N,N′,N-tris(dimethylaminopropyl)-s-hexahydrotriazine, diazabicyclononane, diazabicycloundecane, 1,1,3,3-tetramethylguanidine, 1,3,4,6,7,8-hexahydro-1-methyl-2H-pyrimido(1,2-a)pyrimidine, are particularly preferred.

Particularly preferred catalysts are dibutyltin dilaurate, dimethyltin dicarboxylate, iron(III) acetylacetonate, 1,4-diazabicyclo[2.2.2]octane, diazabicyclononane, diazabicycloundecane, 1,1,3,3-tetramethylguanidine and 1,3,4,6,7,8-hexahydro-1-methyl-2H-pyrimido(1,2-a)pyrimidine.

In addition, further auxiliaries and additives may also be present in the PU systems according to the invention. These are, for example, solvents, plasticizers, leveling agents, antifoams or adhesion promoters, but also polyurethanes, thermoplastic polymers, oligomers, and further compounds having functional groups, such as, for example acetals, epoxide, oxetanes, oxazolines, dioxolanes and/or hydrophilic groups, such as, for example, salts and/or polyethylene oxides.

Preferably used solvents are readily volatile solvents having good compatibility with the 2-component formulations according to the invention, for example ethyl acetate, butyl acetate or acetone.

Liquids having good dissolution properties, low volatility and a high boiling point are preferably used as plasticizers; these may be, for example, diisobutyl adipate, di-n-butyl adipate, dibutyl phthalate, non-hydroxy-functional polyethers, such as, for example, polyethylene glycol dimethyl ether having a number average molar mass of from 250 g/mol to 2000 g/mol or polypropylene glycol and mixtures of said compounds.

It may also be advantageous simultaneously to use a plurality of additives of one type. Of course, it may also be advantageous to use a plurality of additives of a plurality of types.

The mixture of the components B) to F) and optionally catalysts and auxiliaries and additives usually consists of

24.999-99.899% by weight of component B)
0.1-75% by weight of component C)
0-3% by weight of component D)
0.001-5% by weight of component B)
0-4°% by weight of catalysts
0-50% by weight of auxiliaries and additives.

The mixture preferably consists of

86.998-97.998% by weight of component B)
2-13% by weight of component C)
0.001-1% by weight of component D)
0.001-1% by weight of component E)
0-2% by weight of catalysts
0-15% by weight of auxiliaries and additives.

The mixture likewise preferably consists of

44.8-87.8% by weight of component B)
12.5-55% by weight of component C)
0.1-3% by weight of component D)
0.1-3% by weight of component E)
0-3% by weight of catalysts
0-50% by weight of auxiliaries and additives.

The molar ratio of NCO to OH is typically from 0.5 to 2.0, preferably from 0.90 to 1.25.

The PU systems according to the invention are usually obtained by a procedure in which first all components, except for the polyisocyanates A) are mixed with one another. This can be achieved by all methods and apparatuses known per se to the person skilled in the art from mixing technology, such as, for example stirred vessels or both dynamic and static mixers. The temperatures during this procedure are from 0 to 100° C., preferably from 10 to 80° C., particularly preferably from 20 to 60° C. This mixture can immediately be further processed or can be stored as a storage-stable, intermediate, optionally for several months.

If necessary, degassing can also be carried out under a vacuum of, for example, 1 mbar.

The mixing with the polyisocyanate component A) is then effected shortly before the application, it likewise being possible to use the customary mixing techniques. However, apparatuses without any, or with only little dead space are preferred. Furthermore, methods in which the mixing is effected within a very short time and with very vigorous mixing of the two mixed components are preferred. Dynamic mixers, in particular those in which the components A) and B) to E) first come into contact with one another in the mixer are particularly suitable for this purpose. This mixing can be effected at temperatures of from 0 to 80° C., preferably at from 5 to 50° C., particularly preferably from 10 to 40° C. The mixture of the two components A and B can optionally also be degassed after the mixing under a vacuum of, for example, 1 mbar in order to remove the residual gases and to prevent the formation of bubbles in the polymer layer. The mixing gives a clear, liquid formulation which, depending on the composition, cures within a few seconds to a few hours at room temperature.

The PU systems according to the invention are preferably adjusted so that the curing at room temperature begins within minutes to one hour. In a preferred embodiment, the curing is accelerated by heating the formulation after mixing to temperatures between 30 and 180° C., preferably from 40 to 120° C., particularly preferably from 50 to 100° C.

Immediately after mixing of all components, the polyurethane systems according to the invention have viscosities at room temperature of, typically from 10 to 100 000 mPa·s, preferably from 100 to 20 000 mPa·s, particularly preferably from 500 to 10 000 mPa·s, so that they have very good processing properties even in solvent-free form. In a solution with suitable solvents viscosities at room temperature of less than 10 000 mPa·s, preferably less than 2000 mPa·s, particularly preferably less than 500 mPa·s, can be established.

The present invention furthermore relates to the polymers obtainable from PU systems according to the invention.

These preferably have glass transition temperatures of less than −10° C., preferably less than −25° C. and particularly preferably less than −40° C.

According to a preferred process the formulation according to the invention is applied directly after mixing to a substrate it being possible to use all customary methods known to the person skilled in the art in coating technology; in particular, the coating can be applied by knife coating, casting, printing, screen printing, spraying or inkjet printing.

The substrates may be plastic, metal, wood, paper, glass, ceramic and composite materials comprising a plurality of these materials, in a preferred embodiment the substrate having the form of a sheet.

In a preferred embodiment, the coating of the substrate with the formulation is carried out in a continuous process. As a rule the formulation according to the invention is applied as a film having a thickness of from 5 mm to 1 μm, preferably from 500 μm to 5 μm, particularly preferably from 50 μm to 8 μm and very particularly preferably from 25 μm to 10 μm to the substrate.

In the case of a sheet as a substrate, flexible, coated sheets are thus obtained, which sheets, in the case of a continuous process, can be rolled up after curing and thus stored over several months.

In a further preferred embodiment, the formulation is applied so that it is covered on both sides by transparent substrates, in particular plastic or glass, for this purpose the formulation being poured between the substrates held at an exact spacing of from 1 to 2 mm, preferably from 1.2 to 1.8 mm, particularly preferably from 1.4 to 1.6 mm, in particular 1.5 mm, and the substrates being kept at the exact spacing until the formulation has completely solidified and can no longer flow.

The materials used as the substrate can of course have a plurality of layers. It is possible both for the substrate to consist of layers of a plurality of different materials and for it additionally to have, for example, coatings having additional properties, such as improved adhesion, enhanced hydrophobic or hydrophilic properties, improved scratch resistance, antireflection properties in certain wavelength ranges, improved evenness of the surface, etc.

The materials obtained by one of the methods described can then be used for the recording of holograms. For this purpose, two light beams are caused to interfere in the material by a method known to the person skilled in the art of holography (P, Hariharan, Optical Holography 2nd Edition, Cambridge University Press, 1996) so that a hologram forms. The exposure of the hologram can be effected both by continuous and by pulsed irradiation. It is optionally also possible to produce more than one hologram by exposure in the same material and at the same point, it being possible to use, for example, the angle multiplexing method known to the person skilled in the art of holography. After the exposure of the hologram, the material can optionally also be exposed to a strong, broadband light source and the hologram then used without further necessary processing steps. The hologram can optionally also be further processed by further processing steps, for example transfer to another substrate, deformed, insert-molded, adhesively bonded to another surface, or covered with a scratch-resistant coating.

The holograms produced by one of the processes described can serve for data storage, for the representation of images which serve, for example, for the three-dimensional representation of persons or objects and for the authentification of a person or of an article, for the production of an optical element having the function of a lens, a mirror, a filter, a diffusion screen, a diffraction element, an optical waveguide and/or a mask.

The invention therefore furthermore relates to the use of the PU systems according to the invention in the production of holographic media, and to the holographic media as such.

### EXAMPLES

### 2-Component Formulation A

The isocyanate-reactive component was prepared from 5.59 g of a difunctional poly(ε-caprolactone)polyol (number average molar mass about 650 g/mol), 0.40 g of 1,4-bis(thionaphthyl)-2-butyl acrylate, 0.030 g of Irgacure OXE 01 (product of Ciba Specialty Chemicals) and 0.020 g of 2,6-di-tert-butyl-4-methylphenol by stirring this mixture at 50° C. until a clear solution was present. 3.54 g of a polyisocyanate obtained from hexane diisocyanate with a high proportion of oxidiazine dione (Desmodur XP 2410, experimental product of Bayer MateriaiScience AG, NCO content: 23.5%) were used as the isocyanate component.

### 2-Component Formulation B

The isocyanate-reactive component was prepared from 2.70 g of a difunctional poly(ε-caprolactone)polyol (number average molar mass about 650 g/mol), 4.05 g of a difunctional poly(tetrahydrofuran)polyol (Terathane 1000, commercial product from Invista, number average molar mass about 1000 g/mol), 0.40 g of 1,4-bis(thionaphthyl)-2-butyl acrylate, 0.030 g of Irgacure OXE 01 (product of Ciba Specialty Chemicals) and 0.020 g of 2,6-di-tert-butyl-4-methylphenol by stirring this mixture at 50° C. until a clear solution was present. 2.80 g of a polyisocyanate obtained from hexane diisocyanate with a high proportion of oxidiazine dione (Desmodur XP 2410, experimental product of Bayer MaterialScience AC, NCO content: 23.5%) was used as the isocyanate component.

### 2-Component Formulation C

The isocyanate-reactive component was prepared from 1.67 g of an approximately trifunctional poly(ε-caprolactone)polyol (number average molar mass about 1000 g/mol), 5.03 g of a difunctional poly(tetrahydrofuran)polyol (Terathane 1000, commercial product of Invista, number average molar mass about 1000 g/mol), 0.40 g of 1,4-bis(thionaphthyl)-2-butyl acrylate, 0.030 g of Irgacure OXE 01 (product of Ciba Specialty Chemicals) and 0.020 g of 2,6-di-tert-butyl-4-methylphenol by stirring this mixture at 50° C. until a clear solution was present. 2.86 g of a polyisocyanate obtained from hexane diisocyanate with a high proportion of uretdione (Desmodur N3400, commercial product of Bayer MaterialScience AG, NCO content: 21.5%) were used as the isocyanate component.

### Comparative Example 2

### Component Formulation D

The isocyanate-reactive component was prepared from 9.02 g of a difunctional poly(tetrahydrofuran)polyol (Terathane 650, commercial product of Invista, number average molar mass about 650 g/mol), 0.60 g of 1,4-bis(thionaphthyl)-2-butyl acrylate, 0.045 g of Irgacure OXE 01 (product of Ciba Specialty Chemicals) and 0.030 g of 2,6-di-tert-butyl-4-methylphenol by stirring this mixture at 50° C. until a clear solution was present. 5.31 g of a polyisocyanate obtained from hexane diisocyanate with a high proportion of oxidiazine dione (Desmodur XP 2410, experimental product of Bayer MaterialScience AG, NCO content: 23.5%) were used as the isocyanate component.

### 2-Component Formulation E

### Is Like STON 482

The isocyanate-reactive component was prepared from 5.797 g of a difunctional poly(ε-caprolactone)polyol (number average molar mass about 650 g/mol), 0.900 g of Propan-2,2-diylbis[(2,6-dibrom-4,1-phenylen)oxy(2-{[3,3,3-tris(4-chlorphenyl)-propanoyl]-oxy}propan-3,1-diyl)oxyethan-2,1-diyl]-diacrylate, 0.030 g of Irgacure OXE 01 (product of Ciba Speciality Chemicals) and 0.020 g of 2,6-di-tert-butyl-4-methylphenol by stirring this mixture at 60° C. until a clear solution was present. 3,252 g of a polyisocyanate obtained from hexane diisocyanate with a high proportion of oxidiazine dione (Desmodur XP 2410, experimental product of Bayer MaterialScience AG, NCO content: 23.5%) were used as the isocyanate component. 0.0015 g of dibutyl-tin-dilaureate were used to accelerate urethanization reaction.

### 2-Component Formulation F

### Is Like STON 487

The isocyanate-reactive component was prepared from 11.705 g of a difunctional poly(ε-caprolactone)polyol (number average molar mass about 650 g/mol), 1.600 g of Propan-2,2-diylbis[(2,6-dibrom-4,1-phenylen)oxy(2-{[3,3,3-tris(4-chlorphenyl)-propanoyl]-oxy}propan-3,1-diyl)oxyethan-2,1-diyl]-diacrylate, 0.060 g of Irgacure OXE 01 (product of Ciba Speciality Chemicals) and 0.040 g of 2,6-di-tert-butyl-4-methylphenol by stirring this mixture at 60° C. until a clear solution was present. 6.594 g of a polyisocyanate obtained from hexane diisocyanate with a high proportion of oxidiazine dione (Desmodur XP 2410, experimental product of Bayer MaterialScience AG, NCO content: 23.5%) were used as the isocyanate component. 0.010 g of Fomrez UL28 catalyst solution dissolved in butyl acetate (10 wt-%) were used to accelerate urethanization reaction.

Test specimens were produced from the 2-component formulations stated in the table by mixing the isocyanate component and the isocyanate-reactive component in the stated ratio with addition of the stated amount of dimethyltin dicarboxylate (Fomrez UL 28, product of GE Silicones) as a urethanization catalyst.

| 2-Component | | Isocyanate-reactive | Urethanization |
|---|---|---|---|
| formulation | Isocyanate | component | catalyst |
| A | 3.54 g | 6.461 g | 0.004 g |
| B | 2.80 g | 7.20 g | 0.004 g |
| C | 2.86 g | 7.140 g | 0.004 g |
| D | 5.31 g | 9.691 g | 0.0045 g |
| E | 3.252 g | 6.747 g | 0.0015 g |
| F | 6.594 g | 13.405 g | 0.0010 g |

The respective mixtures were then applied to a glass plate and covered with a second glass plate with spacers holding the two glass plates a suitable distance apart (e.g. 250 μm) and the mixture wetting the two inner surfaces of the glass plates. For curing, the samples thus prepared were first stored for 30 minutes at room temperature and then cured for two hours at 50° C.

For testing of the optical properties, a correspondingly prepared test specimen was then exposed at points by causing two laser beams (λ=405 nm) to interfere in the test specimen. The appearance of the samples was then rated according to the following classification:

1=Exposed region is detectable with the naked eye only with very great difficulty after a certain observation time.

2=Exposed region can easily be detected immediately with the naked eye.

3=Exposed region shows a strong turbid halo.

The 2-component formulations described were rated as follows:

2-Component
formulation

| | A | B | C | D | E | F |
|---|---|---|---|---|---|---|
| Rating | 1 | 2 | 2 | 2 to 3 | 1 | 1 |

Overall, the formulations A, B, and C, which contain polyester polyols thus showed better transparency than the formulation D which comprises exclusively a polyether polyol.

All the references described above are incorporated by reference in its entirety for all useful purposes.

While there is shown and described certain specific structures embodying the invention, it will be manifest to those skilled in the art that various modifications and rearrangements of the parts may be made without departing from the spirit and scope of the underlying inventive concept and that the same is not limited to the particular forms herein shown and described.

We claim:

1. A polyurethane system comprising
A) a polyisocyanate,
B) a polyol, comprising at least one poly(ε-caprolactone)polyester polyol,
C) a compound which have groups reacting under the action of actinic radiation with
ethylenically unsaturated compounds with polymerization (radiation-curing groups),
D) optionally a free radical stabilizer and
E) optionally a photoinitiator.

2. The polyurethane system according to claim 1, wherein at least 60% by weight of the polyisocyanates of component A) are based on aliphatic and/or cycloaliphatic di- and/or tri isocyanates.

3. The polyurethane system according to claim 1, wherein the polyisocyanate of component A) is dimerized or oligomerized aliphatic and/or cyclolaliphatic diisocyanate or triisocyanate.

4. The polyurethane system according to claim 2, wherein the polyisocyanate of component A) is at least one of the following compounds selected from the group consisting of isocyanurate, uretdione and iminooxadiazinedione based on HDI, 1,8-diisocyanato-4-(isocyanatomethyl)octane.

5. The polyurethane system according to claim 1, wherein the poly(ε-caprolactone)polyester polyol is at least 20% by weight, based on polyols of component B).

6. The polyurethane system according to claim 4, wherein the poly(ε-caprolactone)polyester polyol is at least 40% by weight, based on polyols of component B).

7. The polyurethane system according to claim 1, wherein the poly(ε-caprolactone)polyester polyols of component B) have number average molar mass of 250 to 5000 g/mol and an average OH functionality of from 2 to 4.

8. The polyurethane system according to claim 6, wherein the poly(ε-caprolactone)polyester polyols of component B) have number average molar masses of 500 to 2000 g/mol and an average OH functionality of from 1.5 to 4.

9. The polyurethane system according to claim 1, wherein the system has a molar ratio of NCO to OH groups from 0.90 to 1.25.

10. The polyurethane system according to claim 1, wherein the compound C) is at least one compound selected from the group consisting of 9-vinylcarbazole, vinylnaphthalene, bisphenol A diacrylate, tetrabromobisphenol A diacrylate, 1,4-bis(2-thionaphthyl)-2-buty] acrylate, pentabromophenyl acrylate, naphthyl acrylate and propane-2,2-diylbis[(2,6-dibromo-4,1-phenylene)oxy(2-{[3,3,3-tris(4-chlorophenyl)propanoyl]oxy}propane-3,1-diyl)oxyethane-2,1-diyl] diacrylate.

11. A polymeric plastic comprising the polyurethane system according claim 1.

12. The polymeric plastic according to claim 1, wherein the plastic are layers or moldings.

13. The polymeric plastic according to claim 11, wherein the plastic has a glass transition temperature of less than −10° C.

14. The polymeric plastic according to claim 11, wherein the plastic has a glass transition temperature of less than −40° C.

15. A holographic media comprising at least one polymeric plastic according to claim 11.
